(19) United States
(12) Patent Application Publication
(10) Pub. No.: US 2008/0116561 A1
(43) Pub. Date: May 22, 2008

(54) Chip carrier film having leads with improved strength and semiconductor package utilizing the film

(75) Inventor: Kuang-Hua Liu, Tainan (TW)

Correspondence Address: TROXELL LAW OFFICE PLLC, SUITE 1404, 5205 LEESBURG PIKE, FALLS CHURCH, VA, 22041, US

(73) Assignee: ChipMOS TECHNOLOGIES INC.

(21) Appl. No.: 11/797,646

(22) Filed: May 4, 2007

(30) Foreign Application Priority Data
Nov. 16, 2006 (TW) 095142484

(51) Int. Cl. H01L 23/48

(52) U.S. Cl. 257/690; 257/E23.01

(57) ABSTRACT

A semiconductor chip carrier film with enhanced lead strengths primarily comprises a flexible dielectric layer, a plurality of leads on the dielectric layer, a reinforced metal layer and a solder mask partially covering the leads. Therein, at least one of the leads has a bend covered by the reinforced metal layer; moreover, the solder mask further covers the reinforced metal layer. Therefore, the broken lead issues due to concentrated stresses on the bends can be avoided. A semiconductor package utilizing the chip carrier film is also revealed.

### FIELD OF THE INVENTION

The present invention relates to a chip carrier for semiconductor packages, especially, to a chip carrier film with enhanced lead strengths and to the semiconductor package utilizing the chip carrier film.

### BACKGROUND OF THE INVENTION

According to different applications and functions of semiconductor devices, chip carriers can be chosen from printed circuit boards, lead frames, and thin wiring films, where the advantage of the thin wiring film is flexible and thin. For instance, Tape Carrier Package (TCP) and Chip-On-Film package (COF) both use the thin wiring film as the chip carrier. Before packaging, the thin wiring film constitutes each individual packaging unit among a reel of tape and the packaging work is carried out reel-to-reel.

As shown in FIG. 1 and FIG. 2, a conventional chip carrier film 100 primarily comprises a flexible dielectric layer 110, a plurality of leads 120 and a solder mask 130 where the leads 120 are formed on the flexible dielectric layer 110 and are partially covered by the solder mask 130. Most of the leads 120 can be divided into three portions, outer leads 122, fan-out traces 123, and inner leads 124 where the inner leads 124 are electrically connected to outer leads 122 by the fan-out traces 123 to increase the pitches of the outer leads 122. As shown in FIG. 2, a plated layer 140 is formed on the surfaces of the leads 120 to prevent oxidization of the leads 120 and is exposed at the outer leads 122 for electrical connection to external printed circuit boards or glass substrates. The solder mask 130 has an opening 131 where the inner leads 124 of the leads 120 are exposed to bond with a chip. A plurality of bends 121 are formed at the intersections between the outer leads 122 and the fan-out traces 123 and are usually located at the flexed regions of the chip carrier film 100 while the semiconductor packages are mounted to the external printed circuit boards or glass substrates, where the external stresses tend to concentrate on the bends 121 and lead to breaking 121A of some of the leads 120, as shown in FIG. 1, which eventually causes the semiconductor packages to fail.

### SUMMARY OF THE INVENTION

The main purpose of the present invention is to provide a chip carrier film with enhanced lead strengths and the semiconductor package utilizing the chip carrier film. Reinforced metal layer is applied to enhance the stress-resistant capability of the bends of the leads and further avoid broken leads at the flexed regions of the chip carrier film.

According to the present invention, a chip carrier film with enhanced lead strengths comprises a flexible dielectric layer, a plurality of leads, a reinforced metal layer and a solder mask where the leads are formed on the flexible dielectric layer and at least one of the leads has a bend. The reinforced metal layer is partially formed on the leads to cover the bends. The solder mask is formed on the flexible dielectric layer to partially cover both the leads and the reinforced metal layer. Therefore, the specific portions of the leads on the chip carrier film are reinforced to avoid broken leads incurred by concentrated stresses. Moreover, semiconductor packages utilizing the chip carrier film are also revealed.

### DESCRIPTION OF THE DRAWINGS

FIG. 1 shows a top view of a conventional chip carrier film.

FIG. 2 shows partially a cross-sectional view at the broken lead of the conventional chip carrier film.

FIG. 3 shows a top view of a chip carrier film with enhanced lead strengths according to the first embodiment of the present invention.

FIG. 4 shows partially a cross-sectional view of the chip carrier film according to the first embodiment of the present invention.

FIG. 5 shows a cross-sectional view of a semiconductor package utilizing the chip carrier film according to the first embodiment of the present invention.

FIG. 6 shows a top view of a chip carrier film with enhanced lead strengths according to the second embodiment of the present invention.

FIG. 7 shows partially a cross-sectional view of the chip carrier film according to the second embodiment of the present invention.

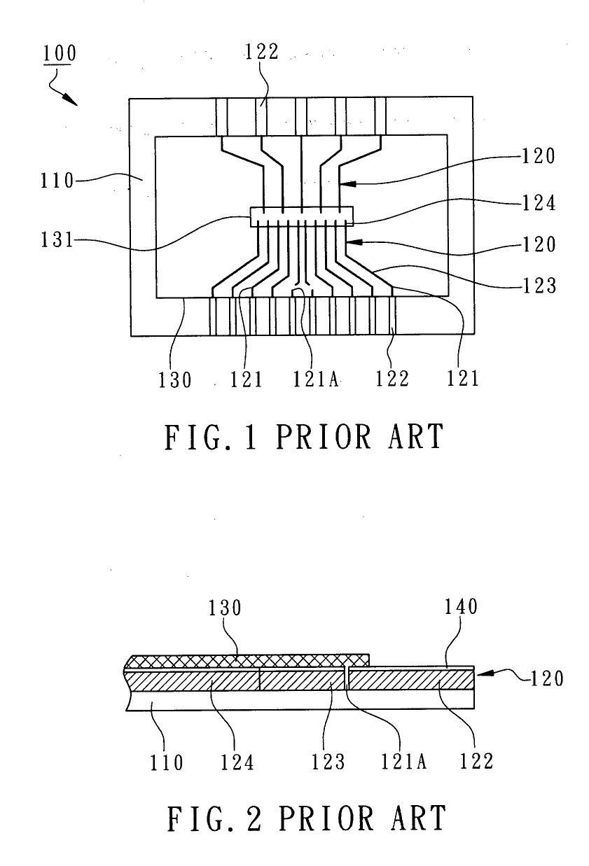

### DETAIL DESCRIPTION OF THE INVENTION

Please refer to the attached drawings, the present invention will be described by means of embodiment(s) below.

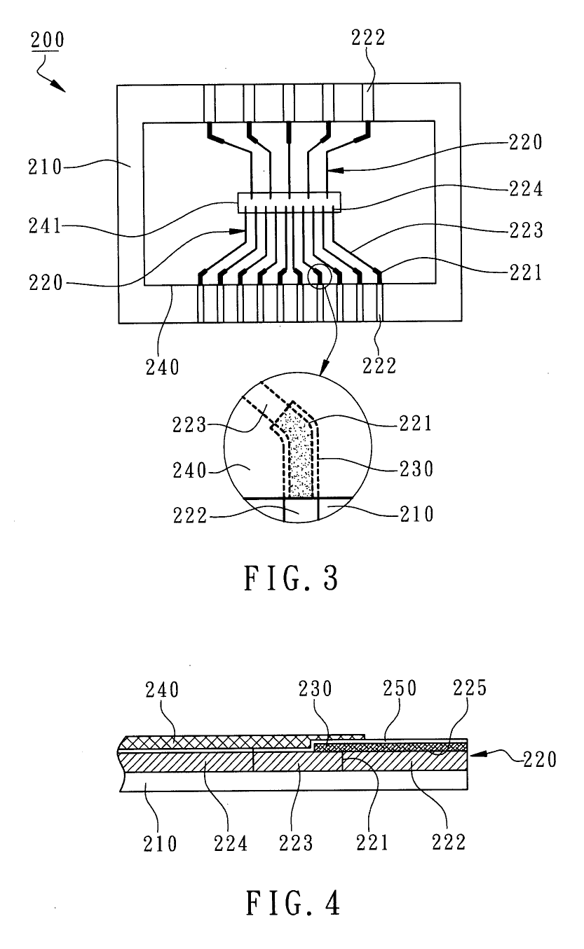

According to the first embodiment of the present invention, as shown in FIG. 3 and FIG. 4, a chip carrier film 200 with enhanced lead strengths primarily comprises a flexible dielectric layer 210, a plurality of leads 220, a reinforced metal layer 230 and a solder mask 240

The flexible dielectric layer 210 is an organic dielectric made of Polyimide (PI), PET, or the like for attachment and electrical isolation of the leads 220. Before packaging, a plurality of chip carrier film 200 are integrally formed on a tape for reel-to-reel semiconductor packaging processes.

The leads 220 are formed on the flexible dielectric layer 210 where the leads 220 are made of high conductive metal such as copper and are relatively thin compared to conventional leads of a lead frame to render flexibility. At least one of the leads 220 has a bend 221 where concentrated stresses tend to occur. Each lead 220 has an outer lead 222, at least a fan-out trace 223 and an inner lead 224 where the smallest angle between the fan-out trace 223 and the outer lead 222 is lying between 90° and 180°. In the present embodiment, the outer leads 222 with a larger pitch are electrically connected to the inner leads 224 with a smaller pitch by the fan-out traces 223. The bends 221 are formed at the intersections of the fan-out traces 223 and the outer leads 222. Furthermore, as shown in FIG. 4, the outer leads 222 has an exposed surface 225 not covered by the solder mask 240 for electrical connection to an external printed circuit board or a glass substrate, not shown in the figure.

The reinforced metal layer 230 is partially formed on the leads 220 to at least cover the bends 221 where the reinforced metal layer 230 has a reverse U-shaped cross-section to serve as a protecting sheath covering the top surface and the two sides of the bend 221 of the lead 220. In the present embodiment, the reinforced metal layer 230 extends onto the exposed surface 225 of the outer leads 222 to thicken the outer leads 222 so that the strength of outer lead bonding (OLB) is better. The reinforced metal layer 230 is made of a material chosen from the group consisting of copper, tin, gold, and silver and is formed by electrical plating. As shown in FIG. 4, the breakage of the leads 220 at the bend 221 can be better avoided by covering the reinforced metal layer 230 with a solder mask. Preferably, a plated layer 250 can be formed above the exposed surface 225 of the outer leads 222, and it may further cover the entire leads 220 including the reinforced metal layer 230 formed above the bend 221 to enhance the coverage of the reinforced metal layer 230 and to avoid oxidization of the reinforced metal layer 230 and the exposed portion of the reinforced metal layer 230.

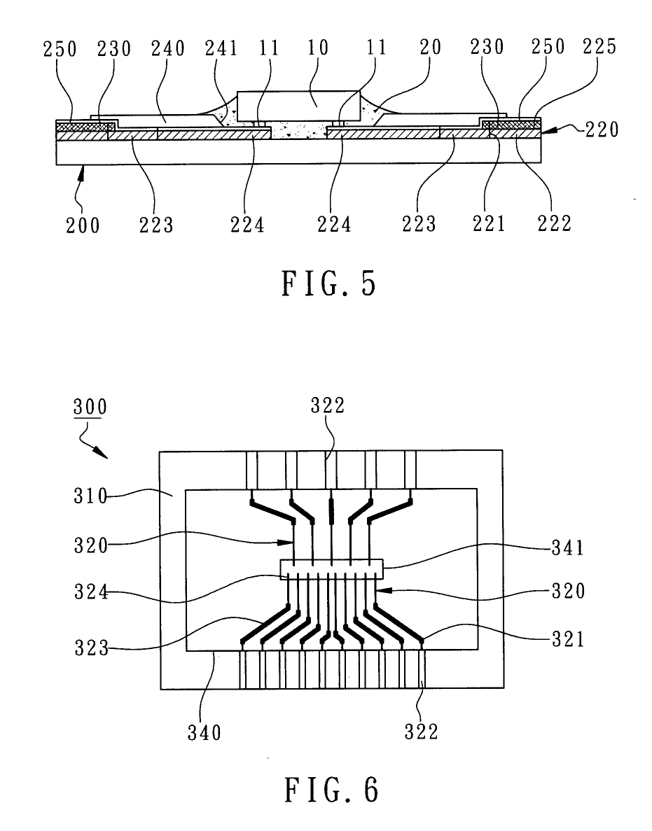

The solder mask 240 is formed on top of the flexible dielectric layer 210 to partially cover the leads 220 and the reinforced metal layer 230 to avoid shorts between the leads 220 due to contamination and to enhance the adhesion of the reinforced metal layer 230. The solder mask 240 has an opening 241 where the inner leads 224 of the leads 220 are exposed to bond with a plurality of bumps 11 on a chip 10, as shown in FIG. 5. Normally, the solder mask 240 can be a liquid photoimagable solder mask (LPI), a photoimagable covering film (PIC), or a non-photosensitive dielectric solder mask or a cover layer.

According to the first embodiment of the present invention, the chip carrier film 200 can further be utilized in semiconductor packages as shown in FIG. 5. A semiconductor package primarily comprises the chip carrier 200 and a chip 10 where the chip is disposed on the chip carrier film 200 and is electrically connected to the leads 220. In the present embodiment, the chip 10 has a plurality of bumps 11 bonded to the inner leads 224 of the leads 220. The semiconductor package further has an encapsulant 20 in high fluidity before curing such as dispensing compounds to encapsulate the bumps 11. The reinforced metal layer 230 is disposed at a flexed region of the chip carrier film 200 located between the chip 10 and the outer leads 122 to avoid breaking of the leads 220 at the bend 221 due to concentrated stresses when the chip carrier film 200 is bent.

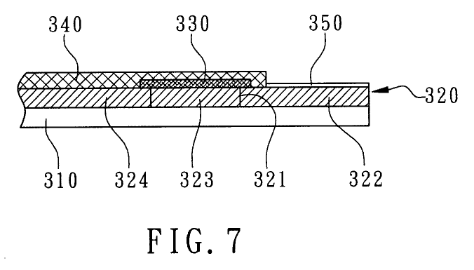

In the second embodiment, another chip carrier film with enhanced lead strengths is revealed as shown in FIG. 6 and FIG. 7. A chip carrier film 300 comprises a flexible dielectric layer 310, a plurality of leads 320, a reinforced metal layer 330 and a solder mask 340 where the leads 320 are formed on the flexible dielectric layer 310 and at least one of the leads 320 has a bend 321. The reinforced metal layer 330 is partially formed on the leads 320 to cover the bend 321. In the present embodiment, the reinforced metal layer 330 can be in the form of a strip to cover only the top surface of a segment of the leads 320 including the bend 321. The solder mask 340 is formed on the flexible dielectric layer 310 to partially cover the leads 320 and to completely cover the reinforced metal layer 330 to enhance the lead strengths of the leads 320 at some specific portions of the chip carrier film 300 and further avoid breaking of the leads 320 due to concentrated stresses.

In the present embodiment, each lead 320 has an outer lead 322, a fan-out trace 323, and an inner lead 324 where the smallest angle between the fan-out trace 323 and the outer lead 322 is lying between 90° and 180°. The bends 321 are located at the intersections between the fan-out traces 323 and the outer leads 322. The outer leads 322 has an exposed surface not covered by the solder mask 340 where a plated layer 350 is formed on the exposed surface but not covering the reinforced metal layer 330. In this embodiment, the reinforced metal layer 330 completely covers the fan-out traces 323. The materials of the reinforced metal layer 330 and the plated layer 350 may be different, for instance, the plated layer 350 can be tin and the reinforced metal layer 330 can be copper. In the present embodiment, the reinforced metal layer 330 covers not only the bends 321 but also the other bends of the fan-out traces 323, not shown in the figure. Furthermore, the inner leads 324 of the leads 320 are partially exposed in the opening 341 of the solder mask 340 for electrical connection to a chip.

The above description of embodiments of this invention is intended to be illustrative and not limiting. Other embodiments of this invention will be obvious to those skilled in the art in view of the above disclosure.

What is claimed is:

1. A chip carrier film with enhanced lead strengths, comprising:
a flexible dielectric layer;
a plurality of leads formed on the dielectric layer, wherein at least one of the leads has a bend;
a reinforced metal layer partially formed on the leads to cover the bend; and
a solder mask formed on the dielectric layer to partially cover the leads and the reinforced metal layer.

2. The chip carrier film of claim 1, wherein each lead has an oblique fan-out trace and an outer lead where the smallest angle between the fan-out trace and the outer lead is lying between 90° and 180°, the bend is located at the intersection between the fan-out trace and the outer lead, and the outer lead has an exposed surface not covered by the solder mask.

3. The chip carrier film of claim 2, further comprising a plated layer formed on the exposed surfaces of the outer leads.

4. The chip carrier film of claim 3, wherein the reinforced metal layer is completely covered by the solder mask.

5. The chip carrier film of claim 2, wherein the reinforced metal layer extends onto the exposed surfaces of the outer leads.

6. The chip carrier film of claim 5, further comprising a plated layer formed on the reinforced metal layer and the leads.

7. The chip carrier film of claim 1, wherein the reinforced metal layer is made of a material chosen from the group consisting of copper, tin, gold and silver.

8. The chip carrier film of claim 1, wherein the reinforced metal layer has a reverse U-shaped cross section to serve as a protecting sheath.

9. The chip carrier film of claim 1, wherein the reinforced metal layer is in the form of a strip.

10. The semiconductor packages comprising:
a chip carrier film comprising:
a flexible dielectric layer;
a plurality of leads formed on the flexible dielectric layer, wherein at least one of the leads has a bend;
a reinforced metal layer partially formed on the leads to cover the bend; and
a solder mask formed on the dielectric layer to partially cover the leads and the reinforced metal layer; and
a chip disposed on the chip carrier film and electrically connected to the leads.

11. The semiconductor package of claim 10, wherein the chip has a plurality of bumps bonded to the leads and the semiconductor package further comprises an encapsulant to encapsulate the bumps.

12. The semiconductor package of claim 10, wherein each lead has a oblique fan-out trace and an outer lead where the smallest angle between the fan-out trace and the outer lead is lying between 90° and 180°, the bend is located at the intersection between the fan-out trace and the outer lead, and the outer lead has an exposed surface not covered by the solder mask.

13. The semiconductor package of claim 12, wherein the chip carrier film further comprises a plated layer formed on the exposed surfaces of the outer leads.

14. The semiconductor package of claim 13, wherein the reinforced metal layer is completely covered by the solder mask.

15. The semiconductor package of claim 12, wherein the reinforced metal layer extends onto the exposed surfaces of the outer leads.

16. The semiconductor package of claim 15, further comprising a plated layer formed on the reinforced metal layer and the leads.

17. The semiconductor package of claim 10, wherein the reinforced metal layer is made of a material chosen from the group consisting of copper, tin, gold and silver.

18. The semiconductor package of claim 10, wherein the reinforced metal layer has a reverse U-shaped cross section to serve as a protecting sheath.

19. The semiconductor package of claim 10, wherein the reinforced metal layer is in the form of a strip.
